(19) United States
(12) Patent Application Publication
(10) Pub. No.: US 2024/0333260 A1
(43) Pub. Date: Oct. 3, 2024

(54) STACKED SURFACE ACOUSTIC WAVE DEVICE

(71) Applicant: Skyworks Solutions, Inc., Irvine, CA (US)

(72) Inventor: Rei Goto, Osaka-Shi (JP)

(21) Appl. No.: 18/608,360

(22) Filed: Mar. 18, 2024

Related U.S. Application Data
(60) Provisional application No. 63/492,693, filed on Mar. 28, 2023.

(51) Int. Cl. H03H 9/64; H03H 9/02; H03H 9/145

(52) U.S. Cl. CPC H03H 9/6453; H03H 9/02637; H03H 9/145

(57) ABSTRACT

A surface acoustic wave device is disclosed. The surface acoustic wave device can include a first interdigital transducer electrode that is in electrical communication with a first piezoelectric layer and a second interdigital transducer electrode that is in electrical communication with a second piezoelectric layer. The first and second interdigital transducer electrodes are positioned between at least a portion of the first piezoelectric layer and at least a portion of the second piezoelectric layer. The first and second interdigital transducer electrodes are positioned such that the second interdigital transducer electrode is configured to transduce a wave generated by the first interdigital transducer electrode. The first interdigital transducer electrode can be an input interdigital transducer electrode, and the second interdigital transducer electrode can be an output interdigital transducer electrode.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/492,693, filed Mar. 28, 2023, titled “STACKED SURFACE ACOUSTIC WAVE DEVICE STRUCTURE,” are hereby incorporated by reference under 37 CFR 1.57 in their entirety.

### BACKGROUND

### Technical Field

Embodiments of this disclosure relate to acoustic wave devices.

### Description of Related Technology

An acoustic wave filter can include a plurality of resonators arranged to filter a radio frequency signal. Example acoustic wave filters include surface acoustic wave (SAW) filters and bulk acoustic wave (BAW) filters. A multi-layer piezoelectric layer (MPS) SAW filter is an example of a SAW filter. A film bulk acoustic resonator (FBAR) filter is an example of a BAW filter.

Acoustic wave filters can be implemented in radio frequency electronic systems. For instance, filters in a radio frequency front end of a mobile phone can include acoustic wave filters. Two acoustic wave filters can be arranged as a duplexer.

### SUMMARY

The innovations described in the claims each have several aspects, no single one of which is solely responsible for its desirable attributes. Without limiting the scope of the claims, some prominent features of this disclosure will now be briefly described.

In some aspects, the techniques described herein relate to a surface acoustic wave device including: a first interdigital transducer electrode in electrical communication with a first piezoelectric layer; and a second interdigital transducer electrode in electrical communication with a second piezoelectric layer, the first and second interdigital transducer electrodes positioned between at least a portion of the first piezoelectric layer and at least a portion of the second piezoelectric layer such that the second interdigital transducer electrode is configured to transduce a wave generated by the first interdigital transducer electrode.

In some embodiments, the techniques described herein relate to an acoustic wave device further including a first pair of reflectors and the first interdigital transducer electrode is positioned longitudinally between the first pair of reflectors.

In some embodiments, the techniques described herein relate to an acoustic wave device further including a second pair of reflectors and the second interdigital transducer electrode is positioned longitudinally between the second pair of reflectors.

In some embodiments, the techniques described herein relate to an acoustic wave device further including a dielectric layer between the first and second piezoelectric layers.

In some embodiments, the techniques described herein relate to an acoustic wave device wherein the dielectric layer is a silicon dioxide layer.

In some embodiments, the techniques described herein relate to an acoustic wave device wherein a thickness of the dielectric layer is in a range of 0.1 L to 0.5 L.

In some embodiments, the techniques described herein relate to an acoustic wave device wherein the first interdigital transducer electrode is an input electrode and the second interdigital transducer electrode is an output electrode.

In some embodiments, the techniques described herein relate to an acoustic wave device wherein a pitch of the first interdigital transducer electrode and a pitch of the second interdigital transducer electrode are the same.

In some embodiments, the techniques described herein relate to an acoustic wave device wherein a pitch of the first interdigital transducer electrode and a pitch of the second interdigital transducer electrode are different.

In some embodiments, the techniques described herein relate to an acoustic wave device further including a first input/output terminal electrically coupled to the first interdigital transducer electrode, and a second input/output terminal electrically coupled to the second interdigital transducer electrode, the first and second input/output terminals exposed on a surface of the acoustic wave device.

In some embodiments, the techniques described herein relate to an acoustic wave device wherein the first input/output terminal electrically coupled to the first interdigital transducer electrode by way of a first conductive via, and the second input/output terminal electrically coupled to the second interdigital transducer electrode by way of a second conductive via.

In some embodiments, the techniques described herein relate to an acoustic wave device wherein the first piezoelectric layer is disposed on a first support substrate and the second piezoelectric layer is disposed on a second support substrate such that the first and second piezoelectric layers are positioned between the first and second support substrates.

In some embodiments, the techniques described herein relate to an acoustic wave device wherein the first interdigital transducer electrode is disposed on, partially within, or embedded in the first piezoelectric layer.

In some aspects, the techniques described herein relate to a surface acoustic wave device including: a first multilayer piezoelectric substrate structure including a first support substrate, a first piezoelectric layer, and an input interdigital transducer electrode connected to the first piezoelectric layer; and a second multilayer piezoelectric substrate structure including a second support substrate, a second piezoelectric layer, and an output interdigital transducer electrode connected to the second piezoelectric layer, the input and output interdigital transducer electrodes positioned between the first and second support substrates.

In some embodiments, the techniques described herein relate to an acoustic wave device further including a first pair of reflectors and a second pair of reflectors, wherein the first interdigital transducer electrode is positioned longitudinally between the first pair of reflectors, and the second interdigital transducer electrode is positioned longitudinally between the second pair of reflectors.

In some embodiments, the techniques described herein relate to an acoustic wave device further including a dielectric layer between the first and second piezoelectric layers.

In some embodiments, the techniques described herein relate to an acoustic wave device wherein a thickness of the dielectric layer is in a range of 0.1 L to 0.5 L.

In some embodiments, the techniques described herein relate to an acoustic wave device further including an input terminal electrically coupled to the input interdigital transducer electrode, and an output terminal electrically coupled to the output interdigital transducer electrode, the input and output terminals exposed on a surface of the acoustic wave device.

In some embodiments, the techniques described herein relate to an acoustic wave device wherein the input and output interdigital transducer electrodes are positioned such that the output interdigital transducer electrode is configured to transduce a wave generated by the input interdigital transducer electrode.

In some embodiments, the techniques described herein relate to an acoustic wave device wherein the first multilayer piezoelectric substrate structure includes a support substrate, a functional layer between the support substrate and the first piezoelectric layer, and a trap rich layer between the support substrate and the functional layer.

In some aspects, the techniques described herein relate to a surface acoustic wave device including: a first multilayer piezoelectric substrate structure including an input interdigital transducer electrode in electrical communication with a first piezoelectric layer; a second multilayer piezoelectric substrate structure including an output interdigital transducer electrode in electrical communication with a second piezoelectric layer, the first and second interdigital transducer electrodes positioned at least partially between the first and second piezoelectric layers and configured to acoustically couple with one another; and a dielectric layer between the input and output interdigital transducer electrodes.

In some embodiments, the techniques described herein relate to an acoustic wave device wherein a thickness of the dielectric layer is in a range of 0.1 L to 0.5 L.

In some embodiments, the techniques described herein relate to an acoustic wave device wherein the thickness of the dielectric layer is in a range of 0.2 L to 0.35 L.

In some embodiments, the techniques described herein relate to an acoustic wave device wherein the first multilayer piezoelectric substrate structure further includes a first pair of reflectors located such that the input interdigital transducer electrode positioned longitudinally between the first pair of reflectors.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a double mode surface acoustic wave (DMS) filter.

FIG. 1B is a schematic plan view of an input interdigital transducer electrode, an output interdigital transducer electrode, and a pair of reflectors.

FIG. 2A is a schematic cross-sectional side view of an acoustic wave device according to an embodiment.

FIG. 2B is a schematic plan view of a first IDT electrode and a first pair of reflectors of the acoustic wave device of FIG. 2A.

FIG. 2C is a schematic plan view of a second IDT electrode and a second pair of reflectors of the acoustic wave device of FIG. 2A.

FIG. 3 shows a simulated frequency response of the DMS filter of FIG. 1A and a simulated frequency response of the acoustic wave device of FIG. 2A.

FIG. 4 is a graph showing the simulated frequency response of the DMS filter of FIG. 1A and simulated frequency responses of the acoustic wave device of FIG. 2A in accordance with various embodiments.

FIG. 5A shows an energy distribution in the DMS filter of FIG. 1A.

FIG. 5B shows an energy distribution in the acoustic wave device of FIG. 2A.

FIG. 6A is a schematic perspective view of the acoustic wave device according to an embodiment.

FIG. 6B is a schematic perspective view of a first structure of the acoustic wave device of FIG. 6A.

FIG. 6C is a schematic perspective view of the second IDT electrode and the second pair of reflectors of the acoustic wave device of FIG. 6A.

FIG. 7A is a schematic plan view of the first IDT electrode and the first pair of reflectors with a first I/O interconnect and a first ground interconnect.

FIG. 7B is a schematic plan view of the second IDT electrode and the second pair of reflectors with a second I/O interconnect and a second ground interconnect.

FIG. 7C is a schematic cross-sectional side view of the acoustic wave device along a plane.

FIG. 7D is a schematic cross-sectional side view of the acoustic wave device along another place.

FIG. 8 is a schematic cross-sectional side view of an acoustic wave device according to an embodiment.

FIG. 9A is a schematic diagram of a radio frequency module that includes a surface acoustic wave component according to an embodiment.

FIG. 9B is a schematic diagram of a radio frequency module that includes filters with surface acoustic wave resonators according to an embodiment.

FIG. 10A is a schematic block diagram of a wireless communication device that includes a filter in accordance with one or more embodiments.

FIG. 10B is a schematic block diagram of another wireless communication device that includes a filter in accordance with one or more embodiments.

FIG. 11 is a schematic block diagram of a wireless communication device that includes a filter according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. The surface acoustic wave devices include, for example, SAW resonators, SAW delay lines, and multi-mode SAW (MMS) filters (e.g., double mode SAW (DMS) filters). Resonators of a MMS filter can be coupled longitudinally along a wave propagation direction to define a multi-mode longitudinally coupled SAW filter.

In general, high quality factor (Q), large effective electromechanical coupling coefficient or coupling factor (K²), high frequency ability, low resistivity, and spurious free can be significant aspects for micro resonators to enable low-loss (e.g., low-insertion loss) filters, stable oscillators, and sensitive sensors. Also, there is a demand for a wider passband to meet the specification of relatively high speed transfer needs. Such a high speed transfer can utilize a radio frequency signal in a fifth generation (5G) New Radio (NR) operating band within Frequency Range 1 (FR1). FR1 can be from 410 megahertz (MHZ) to 7.125 gigahertz (GHz), for example, as specified in a current 5G NR specification. Increasing the passband can be beneficial in mobile device applications that have a need for a wider passband. The passband width of a SAW filter can be determined at least in part by the coupling factor (K²) of a piezoelectric substrate of the SAW filter. However, industrially available piezoelectric materials are limited.

Various embodiments disclosed herein relate to acoustic wave devices that can enable a wider passband by vertically coupling resonators of a filter. According to some embodiments, a SAW filter, such as a multi-mode SAW (MMS) filter, can include a first interdigital transducer (IDT) electrode (e.g., an input IDT electrode) and a second IDT electrode (e.g., an output IDT electrode) that are vertically coupled. For example, the SAW filter can include the first IDT electrode that is in electrical communication with, or connected to, a first piezoelectric layer and the second IDT electrode in electrical communication with, or connected to, a second piezoelectric layer. The first IDT electrode and the second IDT electrode can be positioned at least partially between the first and second piezoelectric layers. The first and second IDT electrodes can be positioned so as to acoustically couple the first and second IDT electrodes. For example, a signal can be input to the first IDT electrode, thereby generating a wave, and the wave generated by the first IDT electrode can be transduced by the second IDT electrode. A bandwidth of a frequency response in a filter that implements an acoustic wave device disclosed herein can provide a significantly wide passband width. Also, various embodiments disclosed herein enable a packageless structure.

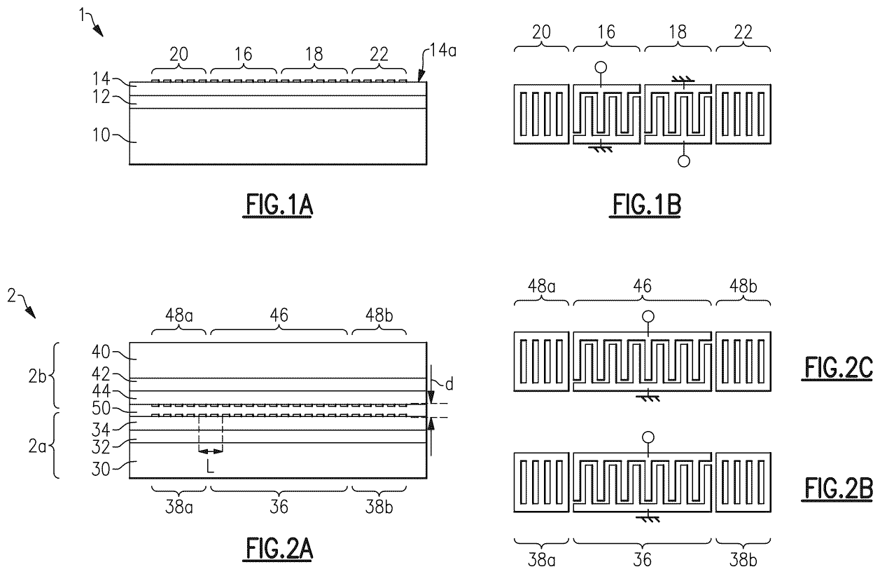

FIG. 1A is a schematic cross-sectional side view of a double mode surface acoustic wave (DMS) filter 1. The DMS filter 1 can include a support substrate 10, a functional layer 12 over the support substrate 10, and a piezoelectric layer 14 over the functional layer 12. The DMS filter 1 can also include an input interdigital transducer electrode 16, an output interdigital transducer electrode 18 longitudinally positioned with the input interdigital transducer electrode 16 along a propagation direction, and a pair of reflectors 20, 22 disposed such that the input and output interdigital transducer electrodes 16, 18 are positioned longitudinally between the pair of reflectors 20, 22.

FIG. 1B is a schematic top plan view of the input interdigital transducer electrode 16, the output interdigital transducer electrode 18, and the pair of reflectors 20, 22. The input interdigital transducer electrode 16, the output interdigital transducer electrode 18, and the pair of reflectors 20, 22 are all disposed on a surface 14a of the piezoelectric layer 14.

The DMS filter 1 having a multilayer piezoelectric substrate (MPS) can enable a relatively low loss filter. However, the DMS filter 1 may not provide a sufficiently wide passband width to meet the specification of relatively high speed transfer needs. Various embodiments disclosed herein relate to acoustic wave devices (e.g., multimode surface acoustic wave filters) that include vertically stacked IDT portions that can provide an acoustic wave device with a relatively low loss and a significantly wide passband width to meet the specification of relatively high speed transfer needs. The vertical direction can be a direction transverse to the wave propagation direction and the finger length direction.

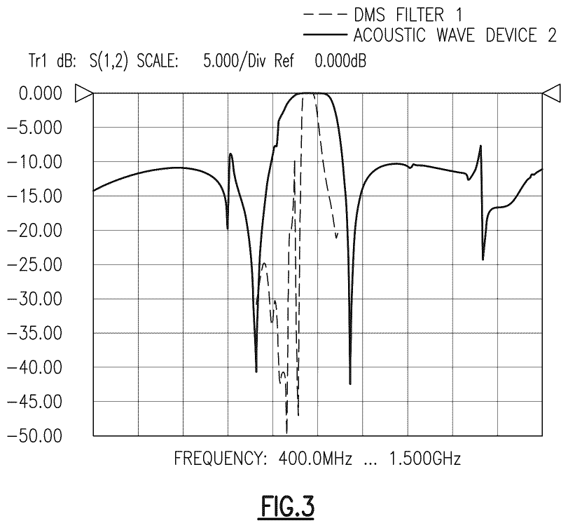

FIG. 2A is a schematic cross-sectional side view of an acoustic wave device 2 according to an embodiment. The acoustic wave device 2 can include a first structure 2a that includes a first support substrate 30, a first functional layer 32, a first piezoelectric layer 34, a first interdigital transducer (IDT) electrode 36, and a first pair of reflectors 38a, 38b. The acoustic wave device 2 can include a second structure 2b that includes a second support substrate 40, a second functional layer 42, a second piezoelectric layer 44, a second IDT electrode 46, and a second pair of reflectors 48a, 48b. The first structure 2a and the second structure 2b can be bonded to one another by way of an intermediate layer 50.

In some embodiments, the first support substrate 30 and/or the second support substrate 40 can be a single crystal layer. In some embodiments, the first support substrate 30 and/or the second support substrate 40 can be a silicon support substrate. In some other embodiments, the first support substrate 30 and/or the second support substrate 40 can include, for example, sapphire, aluminum oxide (Al₂O₃), aluminum nitride (AlN), ceramic material, quartz etc. The first support substrate 30 and/or the second support substrate 40 can have a high impedance relative to the first or second piezoelectric layer 34, 44 and high thermal conductivity. For example, the first support substrate 30 and/or the second support substrate 40 can have a higher impedance than an impedance of the first or second piezoelectric layer 34, 44 and a higher thermal conductivity than a thermal conductivity of the first or second piezoelectric layer 34, 44.

In some embodiments, the first functional layer 32 and/or the second functional layer 42 can act as an adhesive layer. The first functional layer 32 and/or the second functional layer 42 can include any suitable material. The first functional layer 32 and/or the second functional layer 42 can be, for example, an oxide layer (e.g., a silicon dioxide (SiO₂) layer).

The first piezoelectric layer 34 and/or the second piezoelectric layer 44 can be any suitable piezoelectric layer, such as a lithium based piezoelectric layer. In some embodiments, the first piezoelectric layer 34 and/or the second piezoelectric layer 44 can be a lithium tantalate (LT) layer. In some other embodiments, the first piezoelectric layer 34 and/or the second piezoelectric layer 44 can be a lithium niobate (LN) layer. For example, the first piezoelectric layer 34 and/or the second piezoelectric layer 44 can be an LT layer having a cut angle of 42° (42°Y-cut X-propagation LT) or a cut angle of 60° (60° Y-cut X-propagation LT). For example, the first piezoelectric layer 34 and/or the second piezoelectric layer 44 can be 30±20° Y-cut LT, 42±20° Y-cut LT, 42±15° Y-cut LT, 42±10° Y-cut LT, 42±5° Y-cut LT, 60±20° Y-cut LT, 60±15° Y-cut LT, 60±10° Y-cut LT, or 60±5° Y-cut LT. A generally similar cut angles may be also applicable when the LN layer is used for the first piezoelectric layer 34 and/or the second piezoelectric layer 44. A thickness of the first piezoelectric layer 34 and/or the second piezoelectric layer 44 can be selected based on a wavelength λ or L of a surface acoustic wave generated by the SAW device 2 in certain applications. The first piezoelectric layer 34 and/or the second piezoelectric layer 44 can be sufficiently thick to avoid significant frequency variation.

FIG. 2B is a schematic plan view of the first IDT electrode 36 and the first pair of reflectors 38a, 38b. FIG. 2C is a schematic plan view of the second IDT electrode 46 and the second pair of reflectors 48a, 48b. In some embodiments, the first IDT electrode 36 can be an input IDT and the second IDT 46 can be an output IDT. The first and second IDT electrodes 36, 46 can include any suitable material(s). In some embodiments, the first IDT electrode 36 and/or the second IDT electrode 46 can have a multi-layer IDT structure. For example, one layer of the multi-layer IDT structure can include tungsten (W) and the another layer of the multi-layer IDT structure can include aluminum (Al) in certain embodiments. The first IDT electrode 36 and/or the second IDT electrode 46 may include molybdenum (Mo), aluminum (Al), copper (Cu), Magnesium (Mg), titanium (Ti), tungsten (W), the like, or any suitable combination thereof. The first IDT electrode 36 and/or the second IDT electrode 46 may include alloys, such as AlMgCu, AlCu, etc.

The first IDT electrode 36 and the second IDT electrode 46 have a pitch that sets the wavelength λ or L of the acoustic wave device 2. In some embodiments, the first IDT electrode 36 and the second IDT electrode 46 can have the same pitch. In some other embodiments, the first IDT electrode 36 and the second IDT electrode 46 can have different pitches. By varying the pitch(es) of the first IDT electrode 36 and/or the second IDT electrode 46, a lower end or a higher end of the passband may be altered.

In some embodiments, as compared to the DMS filter 1 of FIG. 1A, the acoustic wave device 2 of FIG. 2A can have larger IDT electrodes (e.g., more number of fingers in the first and second IDT electrodes 36, 46) within the same footprint, which can be beneficial for power handling, such as for transmission filter applications. Though the first and second IDT electrodes 36, 46 illustrated in FIG. 2A are disposed on the respective piezoelectric layers 34, 44, the first and/or second IDT electrodes 36, 46 may be at least partially in the respective piezoelectric layers 34, 44. For example, portions of the first and/or second IDT electrodes 36, 46 may be disposed within or embedded in the respective piezoelectric layers 34, 44 and different portions of the first and/or second IDT electrodes 36, 46 may be disposed over the respective piezoelectric layers 34, 44, or the first and/or second IDT electrodes 36, 46 may be completely embedded in the respective piezoelectric layers 34, 44.

The intermediate layer 50 can act as an adhesive layer. The intermediate layer 50 can include any suitable dielectric material. The intermediate layer 50 can be, for example, an oxide layer (e.g., a silicon dioxide (SiO₂) layer) and/or a nitride layer.

In some embodiments, when a signal is input to the first IDT electrode 36, a wave can be generated by the first IDT electrode 36. The wave generated by the first IDT electrode 36 can propagate through the intermediate layer 50. The wave generated by the first IDT electrode 36 can be transduced by the second IDT electrode 46. As compared to the DMS filter 1 of FIGS. 1A and 1B in which the wave generated by the input IDT electrode 16 is transduced by the output IDT electrode 18, the first IDT electrode 36 and the second IDT electrode 46 of the acoustic wave device 2 can be more closely positioned. Therefore, the first IDT electrode 36 and the second IDT electrode 46 can be coupled effectively, which can contribute to providing a relatively wide passband width.

Although the acoustic wave device 2 disclosed herein may include only a pair of the first and second IDT electrodes (e.g., a pair of input and output IDT electrodes), an acoustic wave device can include two or more pairs of IDT electrodes that are arranged in accordance with various embodiments disclosed herein.

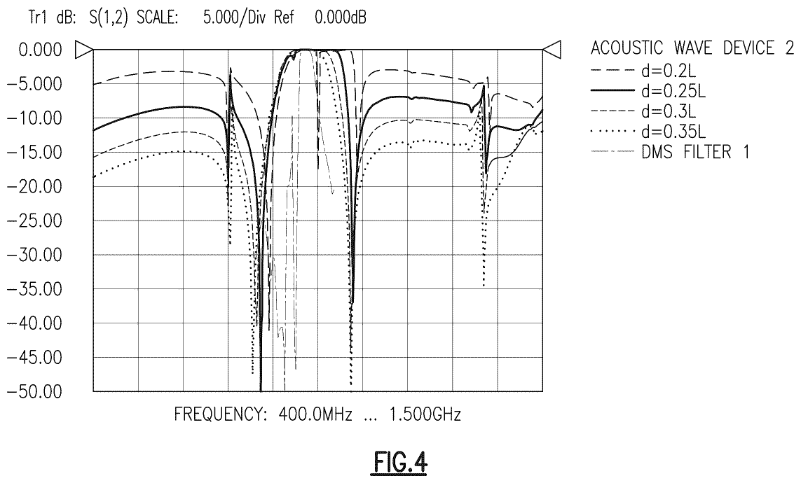

FIG. 3 shows a simulated frequency response of the DMS filter 1 of FIG. 1A and a simulated frequency response of the acoustic wave device 2 of FIG. 2A. The simulation results shown in FIG. 3 indicate that a passband width of the acoustic wave device 2 is significantly wider (e.g., about three times wider) than a passband width of the DMS filter 1. The simulation results shown in FIG. 3 indicate that the acoustic wave device 2 provides relatively large effective electromechanical coupling coefficient or coupling factor (K²).

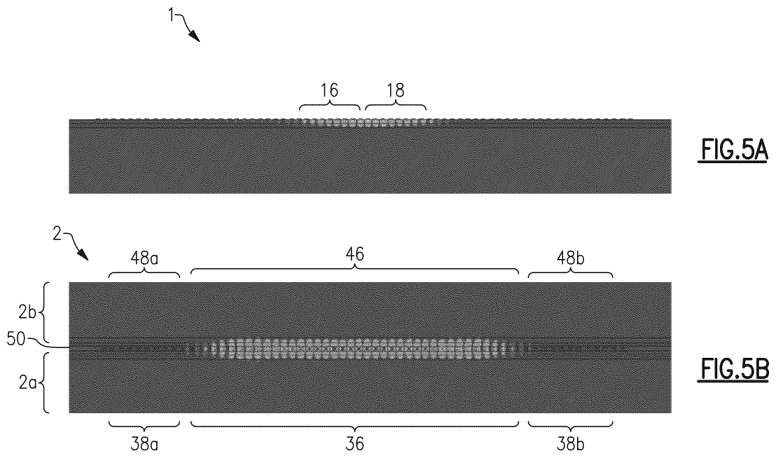

FIG. 4 is a graph showing the simulated frequency response of the DMS filter 1 of FIG. 1A and simulated frequency responses of the acoustic wave device 2 of FIG. 2A with different distances d (d=0.2 L, 0.25 L, 0.3 L, and 0.35 L) between first and second structures 2a, 2b. The simulation results shown in FIG. 4 indicate that the distance between the first and second structures 2a, 2b can affect the passband widths. As the distance d between the first and second structures 2a, 2b gets smaller, the passband width becomes wider. Accordingly, in some applications, it can be beneficial to make the distance d between the first and second structures 2a, 2b as small as possible. For example, the distance d can be slightly (e.g., at least 0.1 L or at least 0.05 L) greater than a sum of the thicknesses of the first and second IDT electrodes 36, 46. In some embodiments, the distance d between the first and second structures 2a, 2b can be in a range of 0.1 L to 0.5 L, 0.2 L to 0.5 L, 0.2 L to 0.4 L, 0.2 L to 0.35 L, 0.25 L to 0.5 L, 0.25 L to 0.4 L, 0.25 L to 0.35 L, or 0.1 L to 0.35 L. Selecting the distance d from these ranges can be critical in providing a significantly wide passband width. In some embodiments, the distance d can be the same as a thickness of the intermediate layer 50. When the first IDT electrode 36 and/or the second IDT electrode 46 is/are partially within the respective piezoelectric layer 34, 44 or embedded in the respective piezoelectric layer 34, 44, the distance d can be even smaller than the above recited ranges.

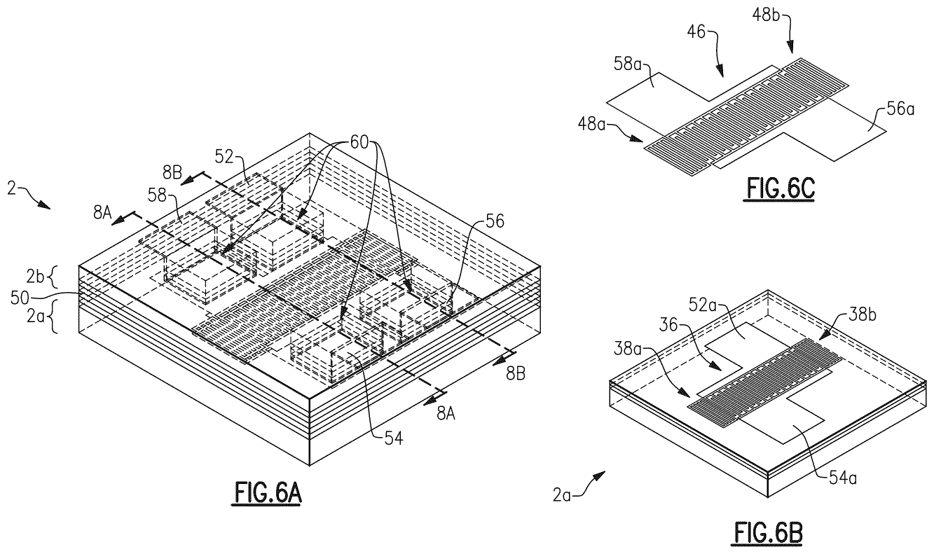

FIG. 5A shows an energy distribution in the DMS filter 1 during operation of the DMS filter 1. FIG. 5B shows an energy distribution in the acoustic wave device 2 during operation of the acoustic wave device 2. FIG. 5B indicates that, as compared to the DMS filter 1 shown in FIG. 5A, the first and second IDT electrodes 36, 46 of the acoustic wave device 2 are acoustically coupled more effectively. Also, FIG. 5B indicates that the waves in the acoustic wave device 2 can be effectively confined by the first and second pairs of the reflectors 38a, 38b, 48a, 48b.

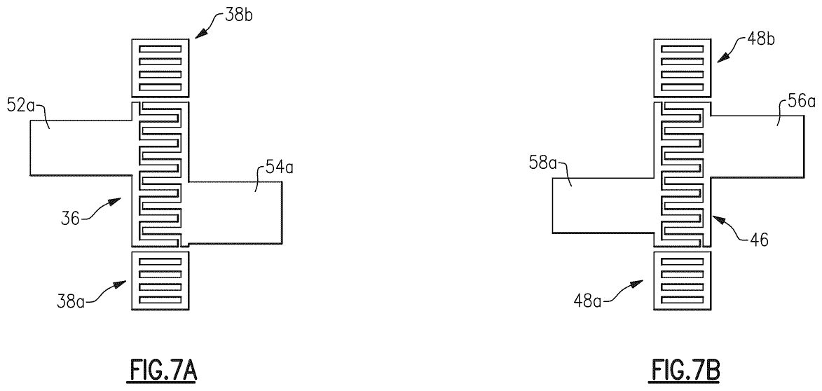

FIG. 6A is a schematic perspective view of the acoustic wave device 2 according to an embodiment. Some components of the acoustic wave device 2 are shown transparent in FIG. 6A to show internal components. FIG. 6B is a schematic perspective view of the first structure 2a of the acoustic wave device 2. FIG. 6C is a schematic perspective view of the second IDT electrode 46 and the second pair of reflectors 48a, 48b of the acoustic wave device 2.

The acoustic wave device 2 can include a first input/output (I/O) terminal 52 and a first ground terminal 54 electrically coupled to a first I/O interconnect 52a and a first ground interconnect 54a of the first IDT electrode 36 respectively, and a second I/O terminal 56 and a second ground terminal 58 electrically coupled to a second I/O interconnect 56a and a second ground interconnect 58a of the second IDT electrode 46 respectively.

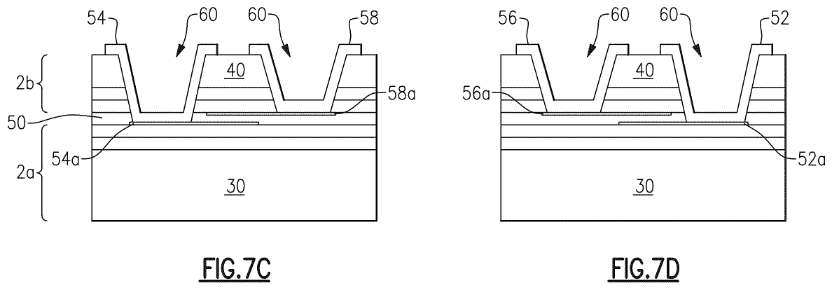

FIG. 7A is a schematic plan view of the first IDT electrode 36 and the first pair of reflectors 38a, 38b with the first I/O interconnect 52a and the first ground interconnect 54a. FIG. 7B is a schematic plan view of the second IDT electrode 46 and the second pair of reflectors 48a, 48b with the second I/O interconnect 56a and the second ground interconnect 58a. FIG. 7C is a schematic cross-sectional side view of the acoustic wave device 2 along the first ground terminal 54 and the second ground terminal 58. FIG. 7D is a schematic cross-sectional side view of the acoustic wave device 2 along the first I/O terminal 52 and the second I/O terminal 56.

The first I/O terminal 52, the first ground terminal 54, the second I/O terminal 56, and the second ground terminal 58 can be electrically coupled respectively to the first I/O interconnect 52a, the first ground interconnect 54a, the second I/O interconnect 56a, and the second ground interconnect 58a by way of vias 60. In some embodiments, the vias 60 can be conformal vias as illustrated in FIGS. 6A, 7C, and 7D. In some other embodiments, the vias 60 can be filled vias. The vias 60 can extend through the second structure 2b to connect the second I/O terminal 56 and the second ground terminal 58 to the second I/O interconnect 56a and the second ground interconnect 58a. The vias 60 can extend through the second structure 2b and the intermediate layer 50 to connect the first I/O terminal 52 and the first ground terminal 54 to the first I/O interconnect 52a and the first ground interconnect 54a. In some embodiments, the first and second ground terminals 56, 58 can be combined.

In some embodiments, a method of manufacturing an acoustic wave device (e.g., the acoustic wave device 2) can include preparing a first structure (e.g., the first structure 2a) and a second structure (e.g., the second structure 2b). The method can include bonding the first and second structures 2a, 2b. In some embodiments, a first bonding layer can be provided over a bonding side of the first structure 2a, and a second bonding layer can be provided over a bonding side of the second structure 2b. The first and second bonding layers can be bonded to one another to define an intermediate layer (e.g., the intermediate layer 50). Accordingly, in some embodiments, the intermediate layer 50 can have a multilayer structure. The method can include forming vias 60 at least partially through the second structure 2b and the intermediate layer 50. Any suitable process for forming the vias 60 can be used. In some embodiments, portions of the second structure 2b and the intermediate layer 50 can be removed (e.g., etched), and a conductive material can be provided (e.g., deposited) over the removed portions to form the vias 60. Terminals (e.g., the first ground terminal 54, the second I/O terminal 56, and the second ground terminal 58) can be formed simultaneously with the vias 60 or separately.

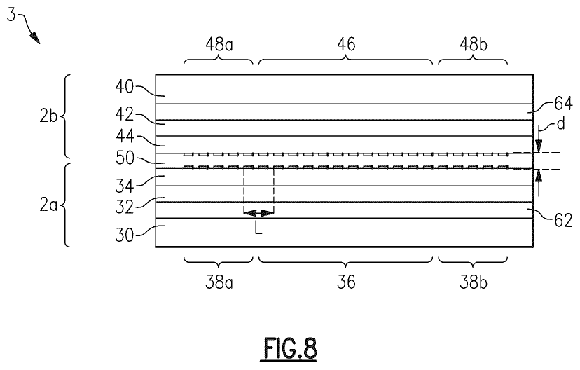

FIG. 8 is a schematic cross-sectional side view of an acoustic wave device 3 according to an embodiment. Unless otherwise noted, components of FIG. 8 can be the same as or generally similar to like components disclosed herein, such as those of FIG. 2A. The acoustic wave device 3 can include a first structure 2a that includes a first support substrate 30, a first functional layer 32, a first piezoelectric layer 34, a first interdigital transducer (IDT) electrode 36, a first pair of reflectors 38a, 38b, and a first trap rich layer 62 between the first support substrate 30 and the first functional layer 32. The acoustic wave device 2 can include a second structure 2b that includes a second support substrate 40, a second functional layer 42, a second piezoelectric layer 44, a second IDT electrode 46, a second pair of reflectors 48a, 48b, and a second trap rich layer 64 between the second support substrate 40 and the second functional layer 42. The first structure 2a and the second structure 2b can be bonded to one another by way of an intermediate layer 50. The

The first support substrate 30, the first functional layer 32, the first piezoelectric layer 34, and the first trap rich layer 62 can together define a multilayer piezoelectric substrate (MPS). Similarly, the second support substrate 40, the second functional layer 42, the second piezoelectric layer 44, and the second trap rich layer 64 can together define a multilayer piezoelectric substrate (MPS). The trap rich layer 62, 64 can include, for example, polycrystalline silicon, amorphous silicon, porous silicon, silicon nitride, or aluminum nitride. The trap rich layer 62, 64 can have a multilayer trap rich structure, in some embodiments. In some embodiments, the trap rich layer 62, 64 may be defined by a region at or near an interface between the support substrate (the first or second support substrate 30, 40) and the functional layer (the first or second functional layer 32, 34), and may not form a discrete layer separate from the support substrate 20 and/or the intermediate layer 22. The trap rich layer 62, 64 can improve the electrical performance to prevent or mitigate the unwanted electrical leakage on the surface of the support substrate (the first or second support substrate 30, 40).

Various embodiments of an acoustic wave device disclosed herein can be implemented in radio frequency electronic systems. For example, acoustic wave devices disclosed herein can be implemented in a radio frequency front end of a mobile phone.

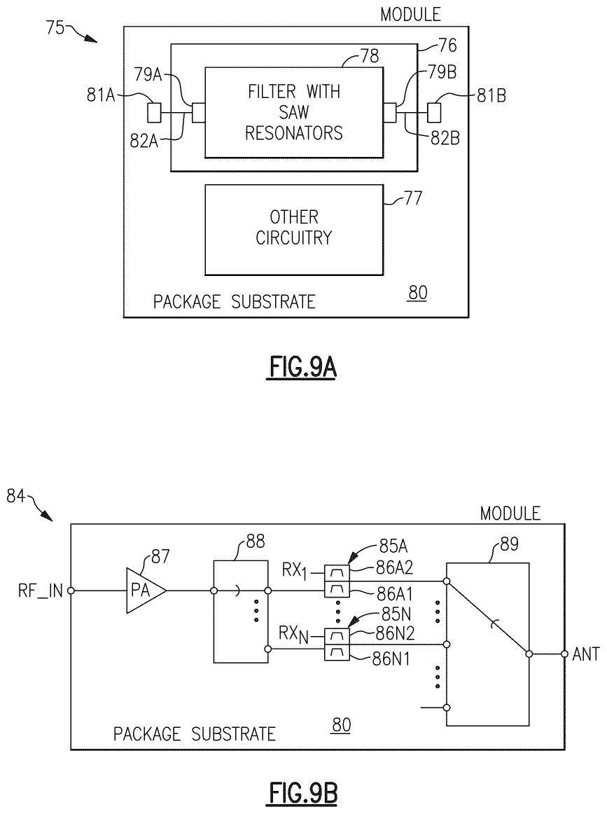

FIG. 9A is a schematic diagram of a radio frequency module 75 that includes a surface acoustic wave component 76 according to an embodiment. The illustrated radio frequency module 75 includes the SAW component 76 and other circuitry 77. The SAW component 76 can include one or more SAW resonators with any suitable combination of features of the SAW resonators and/or acoustic wave devices disclosed herein. The SAW component 76 can include a SAW die that includes SAW resonators.

The SAW component 76 shown in FIG. 9A includes a filter 78 and terminals 79A and 79B. The filter 78 includes SAW resonators. One or more of the SAW resonators can be implemented in accordance with any suitable principles and advantages of any surface acoustic wave resonator disclosed herein. The filter 78 can be a TC-SAW filter arranged as a band pass filter to filter radio frequency signals with frequencies below about 3.5 GHz in certain applications. The terminals 79A and 78B can serve, for example, as an input contact and an output contact. The SAW component 76 and the other circuitry 77 are on a common packaging substrate 80 in FIG. 9A. The packaging substrate 80 can be a laminate substrate. The terminals 79A and 79B can be electrically connected to contacts 81A and 81B, respectively, on the packaging substrate 80 by way of electrical connectors 82A and 82B, respectively. The electrical connectors 82A and 82B can be bumps or wire bonds, for example. The other circuitry 77 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 75 can include one or more packaging structures to, for example, provide protection and/or facilitate easier handling of the radio frequency module 75. Such a packaging structure can include an overmold structure formed over the packaging substrate 80. The overmold structure can encapsulate some or all of the components of the radio frequency module 75.

FIG. 9B is a schematic diagram of a radio frequency module 84 that includes a surface acoustic wave component according to an embodiment. As illustrated, the radio frequency module 84 includes duplexers 85A to 85N that include respective transmit filters 86A1 to 86N1 and respective receive filters 86A2 to 86N2, a power amplifier 87, a select switch 88, and an antenna switch 89. The radio frequency module 84 can include a package that encloses the illustrated elements. The illustrated elements can be disposed on a common packaging substrate 80. The packaging substrate can be a laminate substrate, for example.

The duplexers 85A to 85N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 86A1 to 86N1 can include one or more SAW resonators in accordance with any suitable principles and advantages disclosed herein. Similarly, one or more of the receive filters 86A2 to 86N2 can include one or more SAW resonators in accordance with any suitable principles and advantages disclosed herein. Although FIG. 9B illustrates duplexers, any suitable principles and advantages disclosed herein can be implemented in other multiplexers (e.g., quadplexers, hexaplexers, octoplexers, etc.) and/or in switch-plexers.

The power amplifier 87 can amplify a radio frequency signal. The illustrated switch 88 is a multi-throw radio frequency switch. The switch 88 can electrically couple an output of the power amplifier 87 to a selected transmit filter of the transmit filters 86A1 to 86N1. In some instances, the switch 88 can electrically connect the output of the power amplifier 87 to more than one of the transmit filters 86A1 to 86N1. The antenna switch 89 can selectively couple a signal from one or more of the duplexers 85A to 85N to an antenna port ANT. The duplexers 85A to 85N can be associated with different frequency bands and/or different modes of operation (e.g., different power modes, different signaling modes, etc.).

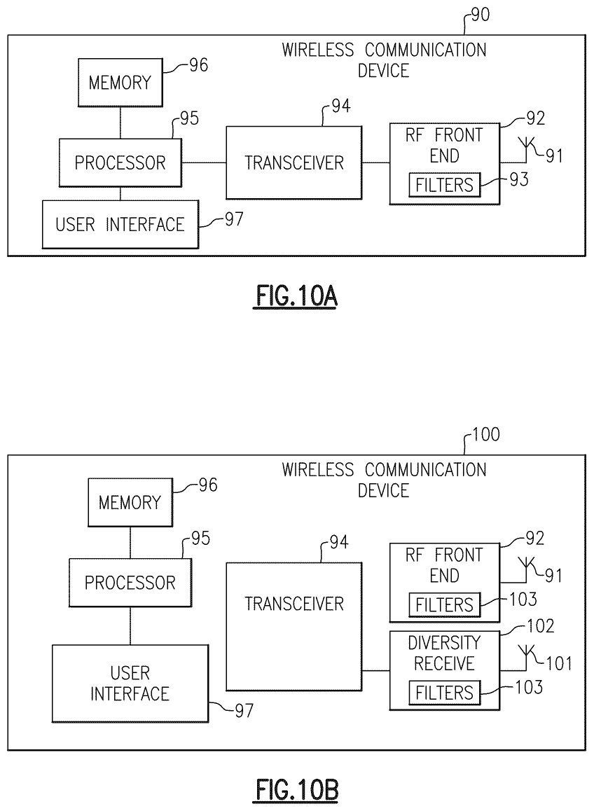

FIG. 10A is a schematic diagram of a wireless communication device 90 that includes filters 93 in a radio frequency front end 92 according to an embodiment. The filters 93 can include one or more SAW resonators in accordance with any suitable principles and advantages discussed herein. The wireless communication device 90 can be any suitable wireless communication device. For instance, a wireless communication device 90 can be a mobile phone, such as a smart phone. As illustrated, the wireless communication device 90 includes an antenna 91, an RF front end 92, a transceiver 94, a processor 95, a memory 96, and a user interface 97. The antenna 91 can transmit RF signals provided by the RF front end 92. Such RF signals can include carrier aggregation signals. Although not illustrated, the wireless communication device 90 can include a microphone and a speaker in certain applications.

The RF front end 92 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 92 can transmit and receive RF signals associated with any suitable communication standards. The filters 93 can include SAW resonators of a SAW component that includes any suitable combination of features discussed with reference to any embodiments discussed above.

The transceiver 94 can provide RF signals to the RF front end 92 for amplification and/or other processing. The transceiver 94 can also process an RF signal provided by a low noise amplifier of the RF front end 92. The transceiver 94 is in communication with the processor 95. The processor 95 can be a baseband processor. The processor 95 can provide any suitable base band processing functions for the wireless communication device 90. The memory 96 can be accessed by the processor 95. The memory 96 can store any suitable data for the wireless communication device 90. The user interface 97 can be any suitable user interface, such as a display with touch screen capabilities.

FIG. 10B is a schematic diagram of a wireless communication device 100 that includes filters 93 in a radio frequency front end 92 and a second filter 103 in a diversity receive module 102. The wireless communication device 100 is like the wireless communication device 90 of FIG. 10A, except that the wireless communication device 100 also includes diversity receive features. As illustrated in FIG. 10B, the wireless communication device 100 includes a diversity antenna 101, a diversity module 102 configured to process signals received by the diversity antenna 101 and including filters 103, and a transceiver 104 in communication with both the radio frequency front end 92 and the diversity receive module 102. The filters 103 can include one or more SAW resonators that include any suitable combination of features discussed with reference to any embodiments discussed above.

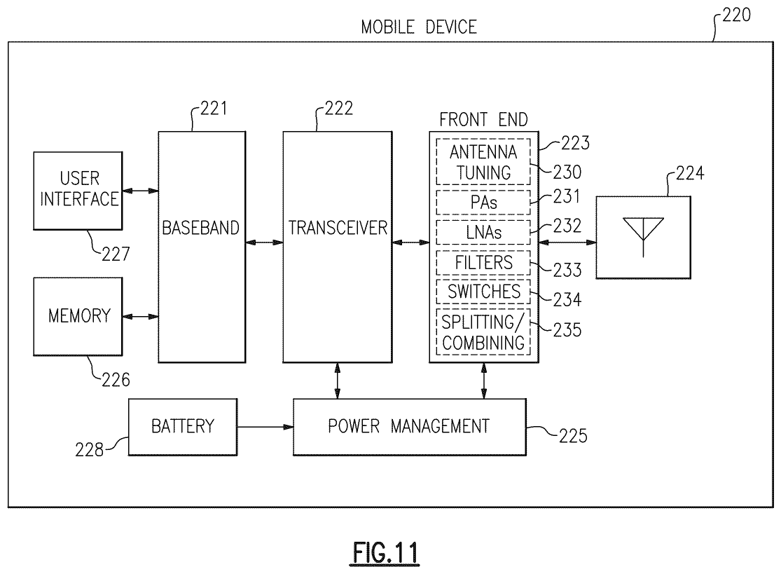

FIG. 11 is a schematic block diagram of a wireless communication device 220 that includes a filter according to an embodiment. The wireless communication device 220 can be a mobile device. The wireless communication device 220 can be any suitable wireless communication device. For instance, a wireless communication device 220 can be a mobile phone, such as a smart phone. As illustrated, the wireless communication device 220 includes a baseband system 221, a transceiver 222, a front end system 223, one or more antennas 224, a power management system 225, a memory 226, a user interface 227, and a battery 228.

The wireless communication device 220 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 222 generates RF signals for transmission and processes incoming RF signals received from the antennas 224. Various functionalities associated with the transmission and receiving of RF signals can be achieved by one or more components that are collectively represented in FIG. 11 as the transceiver 222. In one example, separate components (for instance, separate circuits or dies) can be provided for handling certain types of RF signals.

The front end system 223 aids in conditioning signals provided to and/or received from the antennas 224. In the illustrated embodiment, the front end system 223 includes antenna tuning circuitry 230, power amplifiers (PAs) 231, low noise amplifiers (LNAs) 232, filters 233, switches 234, and signal splitting/combining circuitry 235. However, other implementations are possible. The filters 233 can include one or more acoustic wave filters that include any suitable number of bulk acoustic wave devices in accordance with any suitable principles and advantages disclosed herein.

For example, the front end system 223 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 220 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 224 can include antennas used for a wide variety of types of communications. For example, the antennas 224 can include antennas for transmitting and/or receiving signals associated with a wide variety of frequencies and communications standards.

In certain implementations, the antennas 224 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 220 can operate with beamforming in certain implementations. For example, the front end system 223 can include amplifiers having controllable gain and phase shifters having controllable phase to provide beam formation and directivity for transmission and/or reception of signals using the antennas 224. For example, in the context of signal transmission, the amplitude and phases of the transmit signals provided to the antennas 224 are controlled such that radiated signals from the antennas 224 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 224 from a particular direction. In certain implementations, the antennas 224 include one or more arrays of antenna elements to enhance beamforming.

The baseband system 221 is coupled to the user interface 227 to facilitate processing of various user input and output (I/O), such as voice and data. The baseband system 221 provides the transceiver 222 with digital representations of transmit signals, which the transceiver 222 processes to generate RF signals for transmission. The baseband system 221 also processes digital representations of received signals provided by the transceiver 222. As shown in FIG. 11, the baseband system 221 is coupled to the memory 226 of facilitate operation of the wireless communication device 220.

The memory 226 can be used for a wide variety of purposes, such as storing data and/or instructions to facilitate the operation of the wireless communication device 220 and/or to provide storage of user information.

The power management system 225 provides a number of power management functions of the wireless communication device 220. In certain implementations, the power management system 225 includes a PA supply control circuit that controls the supply voltages of the power amplifiers 231. For example, the power management system 225 can be configured to change the supply voltage(s) provided to one or more of the power amplifiers 231 to improve efficiency, such as power added efficiency (PAE).

As shown in FIG. 11, the power management system 225 receives a battery voltage from the battery 228. The battery 228 can be any suitable battery for use in the wireless communication device 220, including, for example, a lithium-ion battery.

Any suitable principles and advantages of the surface acoustic wave devices disclosed herein can be implemented with one or more temperature compensated SAW resonators. Temperature compensated SAW resonators include a temperature compensation layer (e.g., a silicon dioxide layer) over an interdigital transducer electrode to bring a temperature coefficient of frequency closer to zero.

Packaged surface acoustic wave devices disclosed herein can include one or more surface acoustic wave resonators included in a filter arranged to filter a radio frequency signal in a fourth generation (4G) Long Term Evolution (LTE) operating band. Packaged surface acoustic wave devices disclosed herein can include one or more surface acoustic wave resonators included in a filter arranged to filter a radio frequency signal in a fifth generation (5G) New Radio (NR) operating band within Frequency Range 1 (FR1). FR1 can be from 410 megahertz (MHz) to 7.125 gigahertz (GHz), for example, as specified in a current 5G NR specification. Packaged surface acoustic wave devices disclosed herein can include one or more surface acoustic wave resonators included in a filter with a passband corresponding to both a 4G LTE operating band and a 5G NR operating band within FR1.

Any of the embodiments disclosed herein can combined. Any of the embodiments described above can be implemented in association with a radio frequency system and/or mobile devices such as cellular handsets. The principles and advantages of the embodiments can be used for any systems or apparatus that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals in a frequency range from about 30 KHz to 300 GHz, such as in a frequency range from about 450 MHz to 8.5 GHZ, a frequency range from about 450 MHz to 2.5 GHZ, or a frequency range from about 450 MHz to 3 GHz.

Aspects of this disclosure can be implemented in various electronic devices. Examples of the electronic devices can include, but are not limited to, consumer electronic products, parts of the consumer electronic products such as semiconductor die and/or packaged radio frequency modules, electronic test equipment, uplink wireless communication devices, personal area network communication devices, etc. Examples of the consumer electronic products can include, but are not limited to, a mobile phone such as a smart phone, a wearable computing device such as a smart watch or an ear piece, a telephone, a television, a computer monitor, a computer, a router, a modem, a hand-held computer, a laptop computer, a tablet computer, a personal digital assistant (PDA), a microwave, a refrigerator, a vehicular electronics system such as an automotive electronics system, a stereo system, a DVD player, a CD player, a digital music player such as an MP3 player, a radio, a camcorder, a camera such as a digital camera, a portable memory chip, a washer, a dryer, a washer/dryer, a peripheral device, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A surface acoustic wave device comprising:
a first interdigital transducer electrode in electrical communication with a first piezoelectric layer; and
a second interdigital transducer electrode in electrical communication with a second piezoelectric layer, the first and second interdigital transducer electrodes positioned between at least a portion of the first piezoelectric layer and at least a portion of the second piezoelectric layer such that the second interdigital transducer electrode is configured to transduce a wave generated by the first interdigital transducer electrode.

2. The acoustic wave device of claim 1 further comprising a first pair of reflectors and a second pair of reflectors, wherein the first interdigital transducer electrode is positioned longitudinally between the first pair of reflectors, and the second interdigital transducer electrode is positioned longitudinally between the second pair of reflectors.

3. The acoustic wave device of claim 1 further comprising a dielectric layer between the first and second piezoelectric layers.

4. The acoustic wave device of claim 3 wherein the dielectric layer is a silicon dioxide layer.

5. The acoustic wave device of claim 3 wherein a thickness of the dielectric layer is in a range of 0.1 L to 0.5 L.

6. The acoustic wave device of claim 1 wherein a pitch of the first interdigital transducer electrode and a pitch of the second interdigital transducer electrode are the same.

7. The acoustic wave device of claim 1 wherein a pitch of the first interdigital transducer electrode and a pitch of the second interdigital transducer electrode are different.

8. The acoustic wave device of claim 1 further comprising a first input/output terminal electrically coupled to the first interdigital transducer electrode, and a second input/output terminal electrically coupled to the second interdigital transducer electrode, the first and second input/output terminals exposed on a surface of the acoustic wave device.

9. The acoustic wave device of claim 8 wherein the first input/output terminal electrically coupled to the first interdigital transducer electrode by way of a first conductive via, and the second input/output terminal electrically coupled to the second interdigital transducer electrode by way of a second conductive via.

10. The acoustic wave device of claim 1 wherein the first piezoelectric layer is disposed on a first support substrate and the second piezoelectric layer is disposed on a second support substrate such that the first and second piezoelectric layers are positioned between the first and second support substrates.

11. The acoustic wave device of claim 1 wherein the first interdigital transducer electrode is disposed on, partially within, or embedded in the first piezoelectric layer.

12. A surface acoustic wave device comprising:
a first multilayer piezoelectric substrate structure including a first support substrate, a first piezoelectric layer, and an input interdigital transducer electrode in electrical communication with the first piezoelectric layer; and
a second multilayer piezoelectric substrate structure including a second support substrate, a second piezoelectric layer, and an output interdigital transducer electrode in electrical communication with the second piezoelectric layer, the input and output interdigital transducer electrodes positioned between the first and second support substrates.

13. The acoustic wave device of claim 1 further comprising a first pair of reflectors and a second pair of reflectors, wherein the first interdigital transducer electrode is positioned longitudinally between the first pair of reflectors, and the second interdigital transducer electrode is positioned longitudinally between the second pair of reflectors.

14. The acoustic wave device of claim 12 further comprising a dielectric layer between the first and second piezoelectric layers.

15. The acoustic wave device of claim 14 wherein a thickness of the dielectric layer is in a range of 0.1 L to 0.5 L.

16. The acoustic wave device of claim 12 further comprising an input terminal electrically coupled to the input interdigital transducer electrode, and an output terminal electrically coupled to the output interdigital transducer electrode, the input and output terminals exposed on a surface of the acoustic wave device.

17. The acoustic wave device of claim 12 wherein the first multilayer piezoelectric substrate structure includes a support substrate, a functional layer between the support substrate and the first piezoelectric layer, and a trap rich layer between the support substrate and the functional layer.

18. A surface acoustic wave device comprising:
a first multilayer piezoelectric substrate structure including an input interdigital transducer electrode in electrical communication with a first piezoelectric layer;
a second multilayer piezoelectric substrate structure including an output interdigital transducer electrode in electrical communication with a second piezoelectric layer, the first and second interdigital transducer electrodes positioned at least partially between the first and second piezoelectric layers and configured to acoustically couple with one another; and
a dielectric layer between the input and output interdigital transducer electrodes.

19. The acoustic wave device of claim 18 wherein a thickness of the dielectric layer is in a range of 0.1 L to 0.5 L.

20. The acoustic wave device of claim 19 wherein the thickness of the dielectric layer is in a range of 0.2 L to 0.35 L.
